(19) United States
(12) Patent Application Publication
(10) Pub. No.: US 2024/0363410 A1
(43) Pub. Date: Oct. 31, 2024

(54) METHODS FOR MAKING SEMICONDUCTOR DEVICES THAT INCLUDE METAL CAP LAYERS

(71) Applicant: Tokyo Electron Limited, Tokyo (JP)

(72) Inventors: Ryota Yonezawa, Albany, NY (US); Kai-Hung Yu, Albany, NY (US); Yuji Otsuki, Albany, NY (US); Kenichi Imakita, Albany, NY (US); Atsushi Gomi, Nirasaki City (JP); Kohichi Satoh, Nirasaki City (JP); Tadahiro Ishizaka, Nirasaki City (JP); Takashi Sakuma, Nirasaki City (JP); Hidenao Suzuki, Albany, NY (US)

(21) Appl. No.: 18/620,326

(22) Filed: Mar. 28, 2024

Related U.S. Application Data
(60) Provisional application No. 63/461,678, filed on Apr. 25, 2023.

(51) Int. Cl. H01L 21/768

(52) U.S. Cl. CPC H01L 21/76897; H01L 21/76804; H01L 21/76805

(57) ABSTRACT

A method for forming a semiconductor device can include providing a substrate including a via in a dielectric layer, forming a ruthenium metal plug in the via, and at least part of the ruthenium metal plug can be formed directly on the dielectric layer in the via, forming a metal cap layer directly on the ruthenium metal plug, and forming a metallization layer, such as a copper-containing trench, over the ruthenium metal plug, such that the metal cap layer is between the metallization layer and the ruthenium metal plug, which can prevent intermixing of the ruthenium of the ruthenium metal plug with the metal or metals in the metallization layer.

### CROSS-REFERENCE TO RELATED APPLICATIONS

This application claims the benefit of U.S. Provisional Application No. 63/461,678, filed on Apr. 25, 2023, which application is hereby incorporated herein by reference.

### TECHNICAL FIELD

The present disclosure relates generally to methods for manufacturing semiconductor devices, and more particularly, forming metal cap layers for preventing metal intermixing in interconnects that make electrical connections within semiconductor devices.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other.

Normally, each metal layer must form an electrical contact to at least one additional metal layer. Such electrical contact is achieved by etching a feature (i.e., a via) in the interlayer dielectric layer that separates the metal layers, and filling the resulting via with a metal to create an interconnect. A “via” normally refers to any feature such as a hole, line, or other similar feature formed within a dielectric layer and filled with a metal plug that provides an electrical connection through the dielectric layer to a conductive layer underlying the dielectric layer. Similarly, metal layers connecting two or more vias are normally referred to as “trenches.”

An increase in device performance is normally accompanied by a decrease in device area or an increase in device density. An increase in device density requires a decrease in via dimensions used to form interconnects, including a larger aspect ratio (i.e., depth to width ratio). Copper (Cu) metal is commonly used in multilayer metallization schemes for manufacturing advanced integrated circuits. Problems associated with the use of Cu metal in increasingly smaller features in a substrate will require replacing the Cu metal with one or more low-resistivity metals in those features. Potential problems with having Cu metal in direct physical contact with the one or more low-resistivity metals include metal diffusion that can result in metal intermixing and formation of voids in the metallization structure.

### SUMMARY

In accordance with an embodiment of the present disclosure, a method for forming a semiconductor device can include: providing a substrate including a first via in a first dielectric layer; forming a first ruthenium metal plug in the first via, where at least part of the first ruthenium metal plug is formed directly on the first dielectric layer in the first via; selectively depositing a first self-assembled monolayer (SAM) on the first dielectric layer; selectively depositing a first metal cap layer directly on the first ruthenium metal plug; and forming a first metallization layer over the first ruthenium metal plug, where the first metal cap layer is between the first metallization layer and the first ruthenium metal plug.

In accordance with an embodiment of the present disclosure, a method for forming a semiconductor device can include: providing a substrate including a first dielectric layer having a first metallization layer formed in a first trench thereof, and the substrate further includes a first via in a second dielectric layer, where the second dielectric layer is over at least part of the first dielectric layer and over at least part of the first metallization layer, and where the first via opens to the first metallization layer; forming a first metal cap layer directly on the first metallization layer in the first via; and forming a first ruthenium metal plug in the first via directly on the first metal cap layer.

In accordance with an embodiment of the present disclosure, a method for forming a semiconductor device can include: providing a substrate including a first dielectric layer having a first metallization layer formed therein, and the substrate further including a first trench and a first via in a second dielectric layer, where the second dielectric layer is over at least part of the first dielectric layer and over at least part of the first metallization layer, and where the first via opens to the first metallization layer connecting the first metallization layer to the first trench; forming a first metal cap layer directly on the first metallization layer in the first via; forming a first ruthenium metal plug in the first via directly on the first metal cap layer; and forming a first ruthenium metallization layer in the first trench.

In accordance with an embodiment of the present disclosure, a method for forming a semiconductor device can include: providing a substrate including a first via in a first dielectric layer; forming a first ruthenium metal plug in the first via, where at least part of the first ruthenium metal plug is formed directly on the first dielectric layer in the first via; forming a first metal cap layer directly on the first ruthenium metal plug; and forming a first metallization layer over the first ruthenium metal plug, where the first metal cap layer is between the first metallization layer and the first ruthenium metal plug.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A to 1C are cross-section views illustrating intermediate structures of semiconductor devices made without using a method according to an embodiment of the present disclosure;

FIGS. 2A to 2E are cross-section views illustrating intermediate structures of a semiconductor device made using a method according to an embodiment of the present disclosure;

FIGS. 3A to 3D are cross-section views illustrating intermediate structures of a semiconductor device made using a method according to an embodiment of the present disclosure;

FIGS. 4A to 4E are cross-section views illustrating intermediate structures of a semiconductor device made using a method according to an embodiment of the present disclosure;

FIGS. 5A to 5D are cross-section views illustrating intermediate structures of a semiconductor device made using a method according to an embodiment of the present disclosure;

FIGS. 6A to 6D are cross-section views illustrating intermediate structures of a semiconductor device made using a method according to an embodiment of the present disclosure;

FIGS. 7A to 7C are cross-section views illustrating intermediate structures of a semiconductor device made using a method according to an embodiment of the present disclosure;

FIGS. 8A to 8D are cross-section views illustrating intermediate structures of a semiconductor device made using a method according to an embodiment of the present disclosure;

FIGS. 9A to 9D are cross-section views illustrating intermediate structures of a semiconductor device made using a method according to an embodiment of the present disclosure;

FIGS. 10A to 10D are cross-section views illustrating intermediate structures of a semiconductor device made using a method according to an embodiment of the present disclosure;

FIGS. 11A to 11E are cross-section views illustrating intermediate structures of a semiconductor device made using a method according to an embodiment of the present disclosure;

FIGS. 12A to 12D are cross-section views illustrating intermediate structures of a semiconductor device made using a method according to an embodiment of the present disclosure;

FIGS. 13A to 13D are cross-section views illustrating intermediate structures of a semiconductor device made using a method according to an embodiment of the present disclosure;

FIGS. 14A to 14D are cross-section views illustrating intermediate structures of a semiconductor device made using a method according to an embodiment of the present disclosure;

FIG. 15 illustrates a flow chart implementing the metal cap layer in accordance with an embodiment of the present disclosure;

FIG. 16 illustrates a flow chart implementing the metal cap layer in accordance with an embodiment of the present disclosure;

FIG. 17 illustrates a flow chart implementing the metal cap layer in accordance with an embodiment of the present disclosure; and

FIG. 18 illustrates a flow chart implementing the metal cap layer in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure. Some example embodiments of the present disclosure are described below. Other embodiments can also be understood from the entirety of the specification as well as the claims filed herein.

In the present disclosure, terms such as “first”, “second”, “third”, and “fourth” may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

In the present disclosure and drawings, labels such as “M0”, “M1”, “M2”, and “M3” can be used to describe various metallization levels in the drawings. However, a labeling of metallization levels in the drawings for describing a given example embodiment of the present disclosure may not correspond to the labels used to name or identify actual metallization levels, or to define an actual vertical location thereof, in an actual implementation of an embodiment. Thus, such labels used in the present specification do not necessarily limit the metallization to actual metallization that implements an embodiment of the present disclosure. For example, a metallization level labeled “M1” in present specification may correspond to an actual metallization level located at or designated as level M5 while still being in accordance with an embodiment of the present disclosure.

In some embodiments of the present disclosure, a method for forming a semiconductor device can include providing a substrate including a via in a dielectric layer, forming a ruthenium metal plug in the via, and at least part of the ruthenium metal plug can be formed directly on the dielectric layer in the via, forming a metal cap layer directly on the ruthenium metal plug, and forming a metallization layer, such as a copper-containing trench, over the ruthenium metal plug, such that the metal cap layer is between the metallization layer and the ruthenium metal plug, which can prevent intermixing of the ruthenium of the ruthenium metal plug with the metal or metals in the metallization layer.

In some embodiments of the present disclosure, a method for forming a semiconductor device can include providing a substrate including a via in a dielectric layer that opens to a metallization layer, such as a copper-containing trench, forming a metal cap layer directly on the metallization layer, forming a ruthenium metal plug in the via over or directly on the metal cap layer, and at least part of the ruthenium metal plug can be formed directly on the dielectric layer in the via, such that the metal cap layer is between the metallization layer and the ruthenium metal plug, which can prevent intermixing of the ruthenium of the ruthenium metal plug with the metal or metals in the metallization layer.

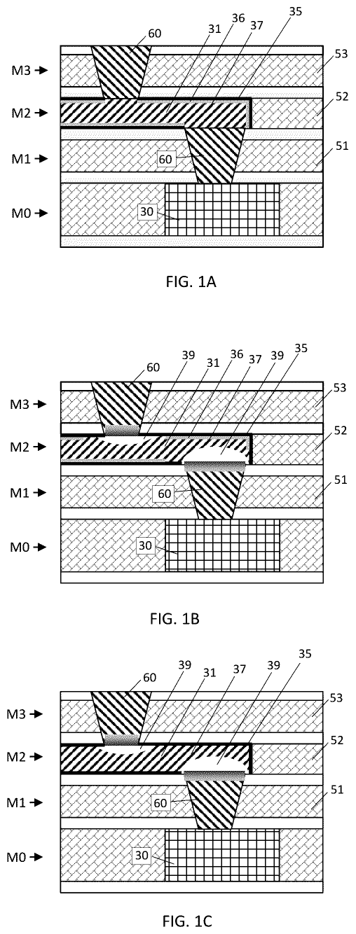

During experimentation and testing for the use of ruthenium as a metal plug for filling a via, problems of forming voids in the metallization layer were found, which was caused by diffusion of copper and cobalt. FIG. 1A schematically shows a portion of a semiconductor device including multilevel metallization interconnects 31, 60 that are formed in dielectric layers 51, 52, 53. In FIG. 1A, the metallization layer 31 is connected by metal filled vias or metal plugs 60. The metal-filled vias or metal plugs 60 can contain ruthenium (Ru) metal that can connect tungsten (W) metal 30 in level M0 with Cu metal 37 in the metallization layer 31 at level M2, and that can connect the metallization layer 31 at level M2 with a higher metallization level (not shown), for example. In another example, the Co metal may be omitted in the metallization level M2. A TaN diffusion barrier layer 35 can separate the Cu metal 37 in the metallization layer 31 from various dielectric materials (e.g., SiO2, SiN, SiCN, low-k) to prevent diffusion of Cu metal into the dielectric materials. The Ru metal filled vias or metal plugs 60 can be formed without using a diffusion barrier layer between the Ru metal and various dielectric materials.

During manufacturing of the semiconductor device, one or more heat-treating steps were performed. FIG. 1B schematically shows problems that were encountered following the one or more heat-treating steps. The heat-treating steps can include annealing under vacuum conditions in the presence of an inert gas at substrate temperatures of about 400° C., for example. Following the one or more heat-treating steps, metal diffusion can be observed that results in Cu metal and Co metal intermixing with Ru metal in addition to Cu migration and formation of voids 39 where no Co metal layer 36 and/or no Cu metal 37 are present, as schematically represented in FIG. 1B. It is speculated that the Co metal and Ru metal intermixing enhances Cu migration. The formation of voids can cause an electrical disconnect or increased resistance in the device, and thus the device may not operate as intended or may fail. Referring to FIG. 1C, in another example the Co metal layer 36 was omitted from the metallization layer 31 (and other levels), and the Cu metal and Ru metal intermixing was also observed, forming voids 39.

In accordance with some embodiments of the present disclosure, the Co/Cu/Ru metal intermixing described with reference to FIGS. 1A to 1C can be prevented or reduced by inserting a thin metal cap layer between Ru metal plugs and metal metallization layers containing Co-doped Cu metal or Cu metal, for example. In some embodiments, the metal cap layer can be selected to provide acceptable low electrical resistance for the multilevel metallization interconnects, and the metal cap layer can contain acceptable low levels of contaminants such as oxygen, nitrogen, hydrogen, halogens, and others, for example.

Some embodiments of the present disclosure make use of a self-assembled monolayer (SAM) as a blocking layer. Generally, SAMs can be molecular assemblies that can be formed selectively on substrate surfaces by adsorption and can be organized into more or less large ordered domains. A SAM can include a molecule that possesses a head group, a tail group, and a functional end group, and a SAM can be created by the chemisorption of head groups onto the substrate from the vapor phase at room temperature or above room temperature, followed by a slow organization of the tail groups. Initially, at small molecular density on the surface, adsorbate molecules can form either a disordered mass of molecules or can form an ordered two-dimensional “lying down phase”, and at higher molecular coverage, over a period of minutes to hours, can begin to form three-dimensional crystalline or semicrystalline structures on the substrate surface. The head groups can assemble together on the substrate, while the tail groups can assemble far from the substrate. The head group of a SAM can include a thiol, a silane, a phosphonate, or a carboxyl group, for example.

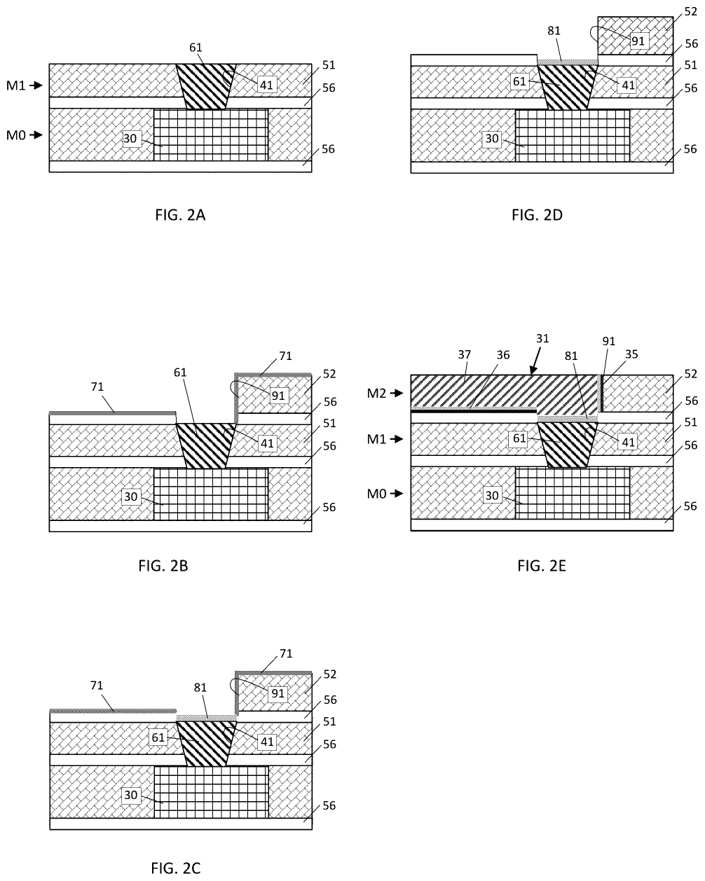

For simplification and illustration purposes, FIGS. 2A to 14D are merely showing some portions of a substrate for a semiconductor device as intermediate structures that can be relevant to a method of making a semiconductor device according to an embodiment of the present disclosure. For example, in FIGS. 2A to 14D, to simplify the drawings, as can be readily understood by one of ordinary skill in the pertinent art, additional layers and structures of a substrate for a semiconductor device made before, under, or below the intermediate structures shown in the drawings are omitted, which can include any structures, types, and semiconductor devices, such as additional interconnects, additional vias, additional trenches, additional interlayer dielectric layers, additional intermetal dielectric layers, additional backend-of-line (BEOL) stage(s) or level(s), frontend-of-line (FEOL) stages or levels, transistors, diodes, capacitors, resistors, inductors, integrated circuits, memory cells, logic, processor portions, digital devices, analog devices, semiconductor wafer, or any combination thereof, for example. Also in FIGS. 2A to 14D, to simplify the drawings, as can be readily understood by one of ordinary skill in the pertinent art, additional layers and structures of a substrate for a semiconductor device made after, over, or above the intermediate structures shown in the drawings are omitted, which can include any structures, types, and semiconductor devices, such as additional interconnects, additional vias, additional trenches, additional interlayer dielectric layers, additional intermetal dielectric layers, additional backend-of-line (BEOL) stage(s) or level(s), passivation layers, contact pads, local interconnects, global interconnects, wire bonding, packaging, or any combination thereof, for example. Furthermore, in an actual completed semiconductor device cross-section, the intermediate structures that are illustrated and represented in the drawings of the present disclosure in a simplified manner as having squared edges and/or linear shapes can be actually more rounded, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on the scale of atoms to less than 5 nanometers in size).

FIGS. 2A to 2E are cross-section views illustrating intermediate structures having metallization levels M0-M2 of a semiconductor device made using a method including a use of a SAM and removing part of or all of the SAM, according to an embodiment of the present disclosure. Referring to FIG. 2A, an intermediate structure can include a metal contact or non-copper-containing metal layer 30, such as a tungsten metal contact or metallization interconnect at a base interconnect level M0 of the intermetal and interlayer dielectric layers (e.g., a “zero” level), a first via 41 formed in a first dielectric layer 51 at level M1, etch stop layers 56, and a first metal plug 61 in the first via 41, for example. In FIG. 2A, the intermediate structure can be after a chemical mechanical polishing or planarization (CMP) processing operation, such as removing excess material formed on top of the first dielectric layer 51 during the forming or deposition of the first metal plug 61, for example. In some embodiments, the first metal plug 61 in the first via 41 can be a first ruthenium metal plug containing ruthenium (Ru). In conventional metal plugs for vias that used copper, a barrier layer was used between the copper and the dielectric material to prevent the copper material from protruding into adjacent the dielectric materials, which can cause shorts and unwanted electrical characteristics. In some embodiments, an advantage of using ruthenium as a metal material or conducting material for a metal plug and/or conducting line in an embodiment is that the ruthenium can be formed or deposited directly on the adjacent dielectric materials, such as the sidewalls of a via opening, which can reduce processing steps and reduce via width because a barrier layer between the metal plug and the adjacent dielectric material can be omitted. In some embodiments, this advantage can provide for additional advantages of increased device density and smaller device area, which is typically an ongoing goal for improving and progressing the technology of semiconductor devices.

Even though the first metal plug 61 is illustrated and represented in the drawings as a single layer of one material, in some embodiments, this first metal plug 61 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the first metal plug 61 can be formed using physical vapor deposition (PVD), chemical vapor deposition (CVD), atomic layer deposition (ALD), or any combination thereof, for example.

Referring to FIG. 2B, a first trench 91 can be formed in a second dielectric layer 52 at level M2, and a portion of the first trench 91 can open to a top surface of the first metal plug 61. A first SAM 71 can be selectively deposited as a blocking layer on the dielectric materials of the first dielectric layer 51 at the first trench 91 and of a second dielectric layer 52 by selecting a SAM material that has stronger bonding to dielectric materials than to metal materials, and in particular ruthenium as a metal material for some embodiments. In some embodiments, some example SAM materials can be any SAM material that can be selectively deposited on the dielectric materials by having relatively stronger bonds or adhesion to dielectric materials than to metal or more specifically ruthenium, which can include alkanethiol, for example.

Referring to FIG. 2C, after selectively depositing the first SAM 71, a first metal cap layer 81 can be selectively deposited on the first metal plug 61. Even though the first metal cap layer 81 is illustrated and represented in the drawings as a single layer of one material, in some embodiments, this first metal cap layer 81 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the material(s) of a given metal cap layer can be selected to in view of providing acceptable low electrical resistance for the multilevel metallization interconnects. In some embodiments, such metal material(s) of a given metal cap layer can include niobium, tungsten, tantalum, aluminum, alloys thereof, layers thereof, mixtures thereof, laminates thereof, or generally any combination thereof, for example. In some embodiments, the first metal cap layer 81 can be formed using physical vapor deposition (PVD), chemical vapor deposition (CVD), atomic layer deposition (ALD), or any combination thereof, for example.

Tests and experiments have shown that a metal cap layer containing niobium deposited using PVD, with a thickness in a range of 1 nm to 10 nm, on a ruthenium metal plug has performed well to prevent, hinder, or significantly reduce intermixing of the ruthenium with cobalt, copper, or cobalt-copper combinations, for example. In some embodiments, a given metal cap layer may be selectively deposited on a ruthenium metal plug using chemical vapor deposition (CVD) or atomic layer deposition (ALD), where metal deposition proceeds rapidly on the ruthenium material but is hindered on the blocking layer. For example, a thickness of a given metal cap layer can be between about 1 nm and about 10 nm, between about 1 nm and about 2 nm, or between about 1 nm and about 5 nm.

Referring to FIG. 2D, a treatment to remove part of, most of, or all of the first SAM 71 can be performed after the forming of the first metal cap layer 81. In some embodiments, such treatment to remove the first SAM 71, or a given SAM, can include a heat-treating step that desorbs the exposed blocking layer from the intermediate structure, for example.

Referring to FIG. 2E, a second metal interconnect level M2 can be further formed and completed over the intermediate structure of FIG. 2D, which can include a first metallization layer 31. The first metallization layer 31 of FIG. 2E can be in a first trench 91 formed in a second dielectric layer 52, and can include a tantalum nitride barrier layer 35 and a cobalt layer 36 lining the first trench 91, and a copper layer 37 filling the first trench 91 as the main conductor for a first metal interconnect or trench, for example. In some embodiments, the first metallization layer 31 (or trench) can contain cobalt, copper, cobalt-doped copper, any composite thereof, any layer combination thereof, any laminate thereof, any mixing thereof, or generally any combination thereof, for example. For purposes of simplifying the description, the tantalum nitride barrier layer 35, the cobalt metal layer 36, and the copper or cobalt-doped copper layer 37 can be part of or incorporated in the first metallization layer 31, and collectively simply referred to as the first metallization layer 31 because the first metallization layer 31 in a given embodiment can include multiple layers and parts therein. In some embodiments, the first metal cap layer 81 (e.g., niobium) is between the first metallization layer 31 (or trench) (e.g., copper/cobalt) and the first metal plug 61 (or metal via) (e.g., ruthenium), such that the first metal cap layer 81 can form or act as a conductive barrier layer between the first metallization layer 31 and the first metal plug 61, for example.

In some embodiments, the diffusion barrier layer of a given metallization layer (at a trench) can be selectively deposited on the one or more dielectric layers relative to a given metal cap layer and/or a given metal plug (at a via). In some embodiments, following the formation of a metallization layer, the device can be annealed under vacuum conditions in the presence of an inert gas at substrate temperatures between about 300° C. and about 450° C., between about 350° C. and about 400° C., between about 350° C. and about 450° C., and between about 400° C. and about 450° C., and the presence of a given metal cap layer according to an embodiment can prevent or hinder metal intermixing between ruthenium and cobalt/copper/cobalt-doped copper and can prevent or hinder formation of voids from metal diffusion.

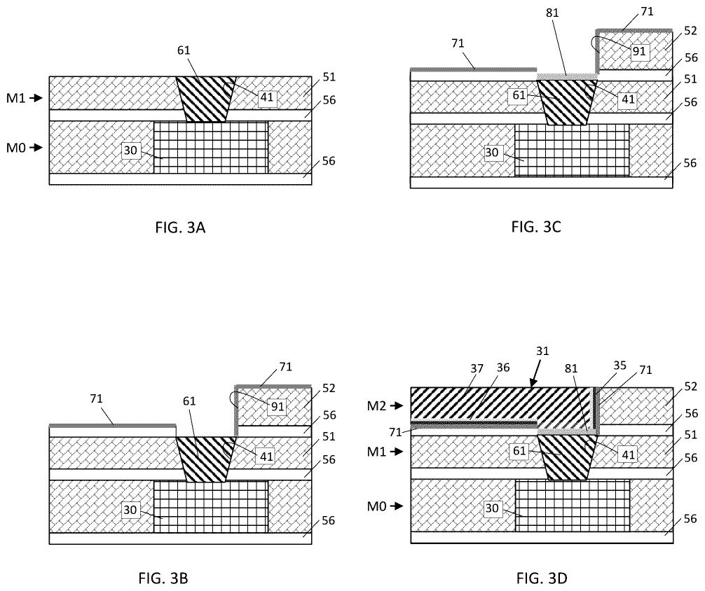

FIGS. 3A to 3D are cross-section views illustrating intermediate structures having metallization levels M0-M2 of a semiconductor device made using a method including a use of a SAM and not removing part of or all of the SAM, according to an embodiment of the present disclosure. The process flow illustrated in FIGS. 3A to 3D can be the same as that shown in and described regarding FIGS. 2A to 2E, except that part of or all of the first SAM 71 is not removed after the formation of the first metal cap layer 81. Thus, referring to FIG. 3D, part of or all of the first SAM 71 can be remaining in the intermediate structure.

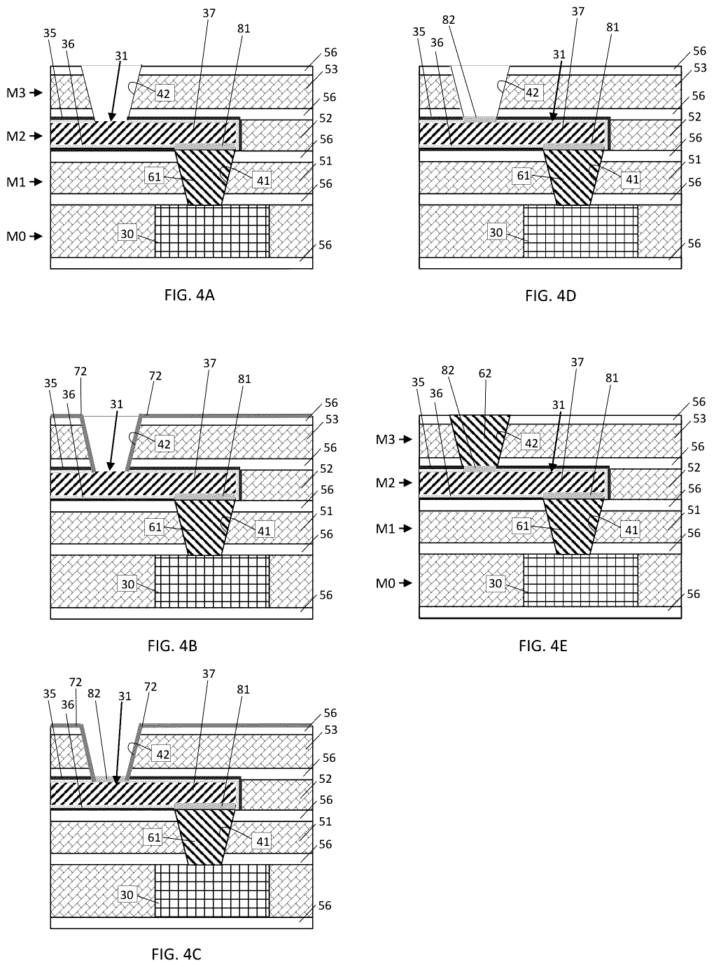

FIGS. 4A to 4E are cross-section views illustrating intermediate structures having metallization levels M0-M3 of a semiconductor device made using a method including a use of a SAM and removing part of or all of the SAM, according to an embodiment of the present disclosure. The intermediate structure shown in FIG. 4A can be a continuation of or built upon the intermediate structure shown in FIG. 2E, for example. And thus, for purposes of concise description, the embodiment of FIGS. 4A to 4E will be described as being built upon and continuing from the description of the intermediate structure of FIG. 2E, and the process steps and intermediate structures leading up to the intermediate structure of FIG. 2E will not be repeated here. Other embodiments can be made in accordance with the embodiment of FIGS. 4A to 4E with different underlying intermediate structures, such as not removing part of or all of the first SAM 71, or no use of SAM, for example.

Referring to FIG. 4A, an intermediate structure can include a second via 42 formed in a third dielectric layer 53 (e.g., a low-k dielectric material), and etch stop layers 56, at level M3. For purposes of simplifying the description, the etch stop layers 56 and any number of dielectric layers at level M3 can be part of or incorporated in the third dielectric layer 53, and collectively simply referred to as the third dielectric layer 53 because the third dielectric layer 53 can include multiple layers and parts therein.

Referring to FIG. 4B, a second SAM 72 can be selectively deposited on the third dielectric layer 53, including on sidewalls of the second via 42 in a conformal manner, by selecting a SAM material that has stronger bonding to dielectric materials than to metal materials, and in particular copper and/or cobalt as a metal material for some embodiments. In some embodiments, some example SAM materials can be any SAM material that can be selectively deposited on the dielectric materials by having relatively stronger bonds or adhesion to dielectric materials than to metal or more specifically copper and/or cobalt, which can include alkanethiol, for example.

Referring to FIG. 4C, after selectively depositing the second SAM 72, a second metal cap layer 82 can be selectively deposited on the first metallization layer 31. Even though the second metal cap layer 82 is illustrated and represented in the drawings as a single layer of one material, in some embodiments, this second metal cap layer can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, such metal material(s) of the second metal cap layer 82 can include niobium, tungsten, tantalum, aluminum, alloys thereof, layers thereof, mixtures thereof, laminates thereof, or generally any combination thereof, for example.

In some embodiments, the second metal cap layer 82 can be formed using physical vapor deposition (PVD), chemical vapor deposition (CVD), atomic layer deposition (ALD), or any combination thereof, for example. In some embodiments, a given metal cap layer may be selectively deposited on underlying metallization layer in the via opening using chemical vapor deposition (CVD) or atomic layer deposition (ALD), where metal deposition proceeds rapidly on the metal material but is hindered on the blocking layer. For example, a thickness of a given metal cap layer can be between about 1 nm and about 10 nm, between about 1 nm and about 2 nm, or between about 1 nm and about 5 nm.

Referring to FIG. 4D, a treatment to remove part of, most of, or all of the second SAM 72 can be performed after the forming of the second metal cap layer 82. In some embodiments, such treatment to remove the second SAM 72 can include a heat-treating step that desorbs the exposed blocking layer from the intermediate structure, for example.

Referring to FIG. 4E, the intermediate structure can be after a CMP processing operation, such as removing excess material formed on top of the third dielectric layer 53 during the forming or deposition of the second metal plug 62, for example. In some embodiments, the second metal plug 62 in the second via 42 can be a second ruthenium metal plug containing ruthenium (Ru). Even though the second metal plug 62 is illustrated and represented in the drawings as a single layer of one material, in some embodiments, this second metal plug 62 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the second metal plug 62 can be formed using physical vapor deposition (PVD), chemical vapor deposition (CVD), atomic layer deposition (ALD), or any combination thereof, for example. In some embodiments, a given metal plug can be ruthenium that is deposited by thermal CVD using a deposition gas containing an organometallic precursor, e.g., organoruthenium compounds. Examples of such organometallic precursors or organoruthenium compounds may include Allylruthenium tricarbonyl, Ru₃(CO)₁₂, (Cyclopentadienyl) Ru(CO)₂X, where X is a halide, and Ruthenocene. The organometallic precursors may be introduced along with reducing agents such as CO, hydrogen, and others. β-diketonate complexes such as Ruthenium (III) acetylacetonate may also be used in some implementations.

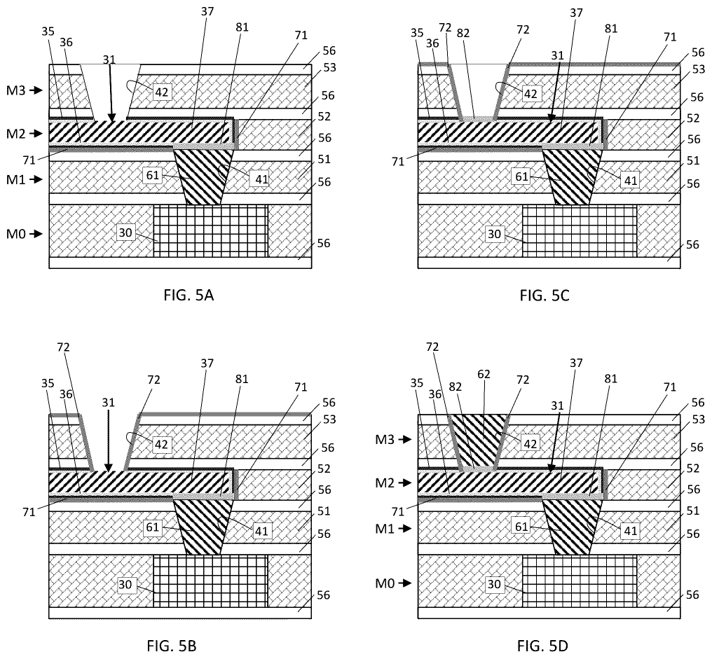

FIGS. 5A to 5D are cross-section views illustrating intermediate structures having metallization levels M0-M3 of a semiconductor device made using a method including a use of a SAM and not removing part of or all of the SAM, according to an embodiment of the present disclosure. The process flow illustrated in FIGS. 5A to 5D can be the same as that shown in and described regarding FIGS. 4A to 4E, except that part of or all of the second SAM 72 is not removed after the formation of the second metal cap layer 82. Thus, referring to FIG. 5D, part of or all of the second SAM 72 can be remaining in the intermediate structure at level M3.

In FIGS. 5A to 5D, part or all of the first SAM 71 is not removed (as in FIG. 3D for example). Other embodiments can be made in accordance with the embodiment of FIGS. 5A to 5D with different underlying intermediate structures, such as the removal of part of or all of the first SAM 71, or no use of SAM, for example.

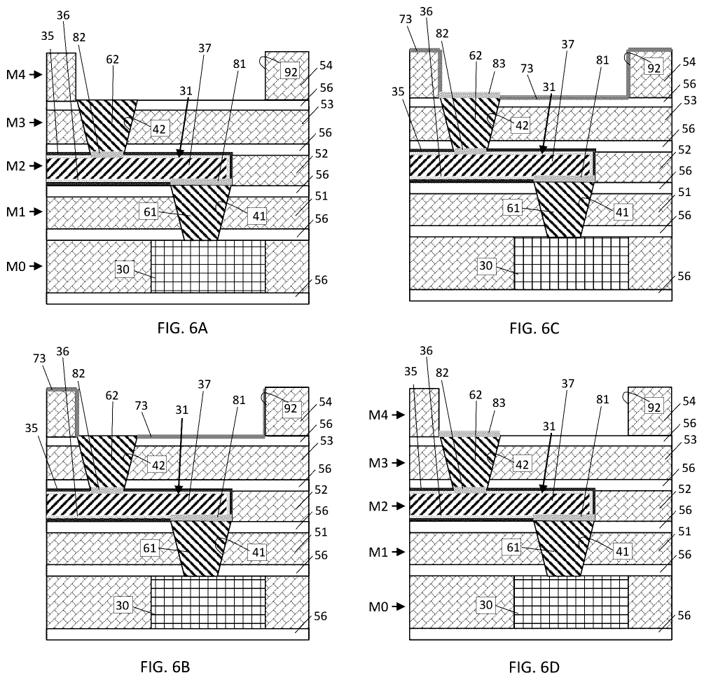

FIGS. 6A to 6D are cross-section views illustrating intermediate structures having metallization levels M0-M4 of a semiconductor device made using a method including a use of a SAM and removing part or all of the SAM according to an embodiment of the present disclosure. The intermediate structure shown in FIG. 6A can be a continuation of or built upon the intermediate structure shown in FIG. 4E, for example. And thus, for purposes of concise description, the embodiment of FIGS. 6A to 6D will be described as being built upon and continuing from the description of the intermediate structure of FIG. 4E, and the process steps and intermediate structures leading up to the intermediate structure of FIG. 4E will not be repeated here. Other embodiments can be made in accordance with the embodiment of FIGS. 6A to 6D with different underlying intermediate structures, such as not removing part of or all of the first SAM 71, not removing part of or all of the second SAM 72, or no use of SAM, for example.

Referring to FIG. 6A, an intermediate structure can include a second trench 92 formed in a fourth dielectric layer 54 (e.g., a low-k dielectric material) at level M4 and opening to or exposing a top of the second metal plug 62, which can be a ruthenium metal plug for example. Even though the fourth dielectric layer 54 is illustrated in FIGS. 6A to 6D as a single layer of one material, the fourth dielectric layer 54 may include multiple layers and parts therein, such as an etch stop layer (not shown), for example. For purposes of simplifying the description, an etch stop layer or layers and any number of dielectric layers can be part of or incorporated in the fourth dielectric layer 54, and collectively simply referred to as the fourth dielectric layer 54 because the fourth dielectric layer 54 can include multiple layers and parts therein.

Referring to FIG. 6B, a third SAM 73 can be selectively deposited on the dielectric materials of the exposed portions of the third dielectric layer 53 in the second trench 92, and of the fourth dielectric layer 54, such as including sidewalls of the second trench 92, by selecting a SAM material that has stronger bonding to dielectric materials than to metal materials, and in particular ruthenium as a metal material for some embodiments.

Referring to FIG. 6C, after selectively depositing the third SAM 73, a third metal cap layer 83 can be selectively deposited on the second metal plug 62. Even though the third metal cap layer 83 is illustrated and represented in the drawings as a single layer of one material, in some embodiments, this third metal cap layer 83 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, such metal material(s) of the third metal cap layer 83 can include niobium, tungsten, tantalum, aluminum, alloys thereof, layers thereof, mixtures thereof, laminates thereof, or generally any combination thereof, for example. In some embodiments, the third metal cap layer 83 can be formed using physical vapor deposition (PVD), chemical vapor deposition (CVD), atomic layer deposition (ALD), or any combination thereof, for example.

Referring to FIG. 6D, a treatment to remove part of, most of, or all of the third SAM 73 can be performed after the forming of the third metal cap layer 83. In some embodiments, such treatment to remove the third SAM 73 can include a heat-treating step that desorbs the exposed blocking layer from the intermediate structure, for example. Subsequent to the intermediate structure shown in FIG. 6D, another metallization layer (not shown) can be formed in the second trench 92, for example.

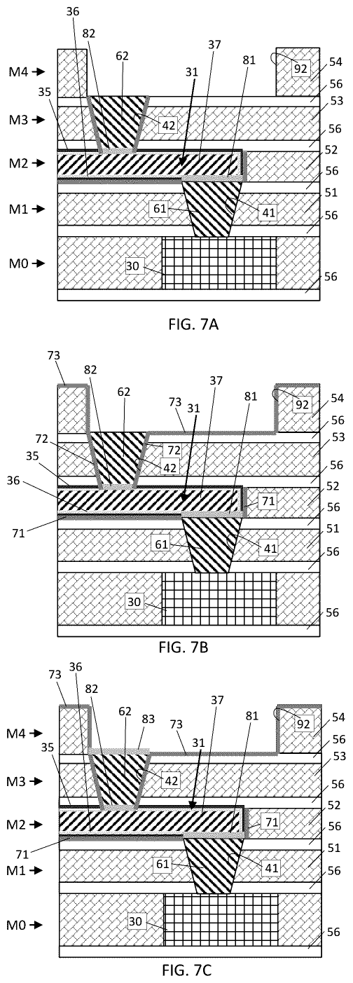

FIGS. 7A to 7C are cross-section views illustrating intermediate structures having metallization levels M0-M4 of a semiconductor device made using a method including a use of a SAM and not removing part or all of the SAM according to an embodiment of the present disclosure. The process flow illustrated in FIGS. 7A to 7C can be the same as that shown in and described regarding FIGS. 6A to 6D, except that part of or all of the third SAM 73 is not removed after the formation of the third metal cap layer 83. Thus, referring to FIG. 7C, part of or all of the third SAM 73 can be remaining in the intermediate structure. Subsequent to the intermediate structure shown in FIG. 7C, another metallization layer (not shown) can be formed in the second trench 92 and on the remaining parts (if any) of the third SAM 73, for example.

In FIGS. 7A to 7C, part or all of the first SAM 71 is not removed (as in FIG. 3D for example) and part or all of the second SAM 72 is not removed (as in FIG. 5D for example). Other embodiments can be made in accordance with the embodiment of FIGS. 7A to 7C with different underlying intermediate structures, such as the removal of part of or all of the first SAM 71, the removal of part of or all of the second SAM 72, no use of SAM at certain levels, or any combination thereof, for example.

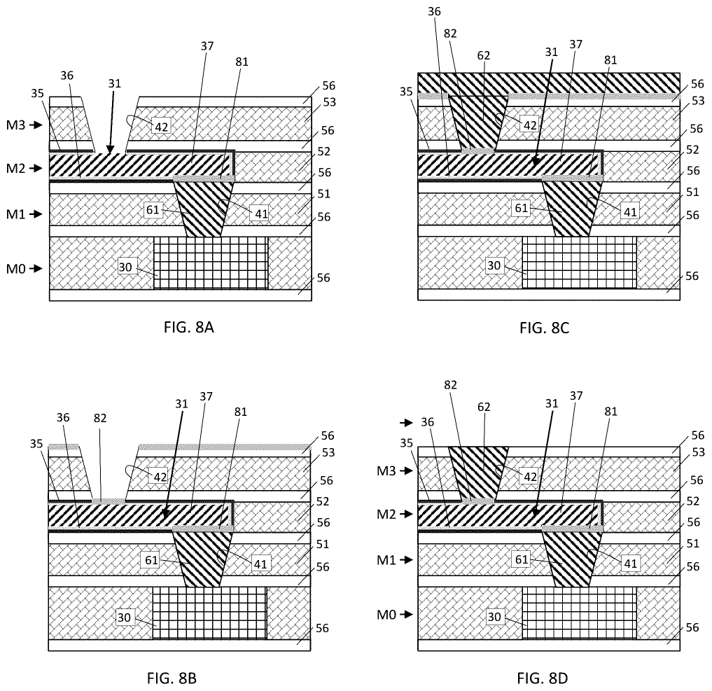

FIGS. 8A to 8D are cross-section views illustrating intermediate structures having metallization levels M0-M3 of a semiconductor device made using a method not using SAM according to an embodiment of the present disclosure. The intermediate structure shown in FIG. 8A can be the same as the intermediate structure shown in FIG. 4A, for example. And thus, for purposes of concise description, the embodiment of FIGS. 8A to 8D will be described as being built upon and continuing from the description of the intermediate structure of FIG. 4A, and the process steps and intermediate structures leading up to the intermediate structure of FIG. 4A will not be repeated here. Other embodiments can be made in accordance with the embodiment of FIGS. 8A to 8D with different underlying intermediate structures, such as not removing part of or all of the first SAM 71, not removing part of or all of the second SAM 72, or no use of SAM, for example.

Referring to FIG. 8B, a second metal cap layer 82 can be formed using a non-conformal deposition process, such as PVD. Using PVD, for example, can form material of the second metal cap layer 82 on the opened first metallization layer 31 at a bottom of the second via 42 (and preferably completely covering the bottom of the second via 82 to completely cover the exposed first metallization layer 31 at the bottom of the second via 82), on a top surface of the third dielectric layer 53, but not on the sidewalls of the second via 42, partly not on upper portions of the sidewalls of the second via 42, mostly not on the sidewalls of the second via 42, or only very minimally on upper portions of the sidewalls of second via 42 (e.g., thicker at lower portions of the sidewalls of the second via 42 than upper portions of the sidewalls of the second via 42). The machine used for the PVD, as well as the conditions and process parameters of the PVD can be adjusted, to control or vary the resulting structure and thickness of the second metal cap layer 82 formed. Hence, the intermediate structure including the formed second metal cap layer 82 illustrated in FIG. 8B can be somewhat simplified and idealized relative to an actual intermediate structure formed according to an embodiment of the present disclosure, as can be apparent to one of ordinary skill in the pertinent art.

Still referring to FIG. 8B, even though the second metal cap layer 82 is illustrated and represented in the drawings as a single layer of one material, in some embodiments, this second metal cap layer 82 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, such metal material(s) of the second metal cap layer 82 can include niobium, tungsten, tantalum, aluminum, alloys thereof, layers thereof, mixtures thereof, laminates thereof, or generally any combination thereof, for example.

Referring to FIG. 8C, the material for the second metal plug 62 can be formed for partially, mostly, completely, or overflowingly filling the second via 42, in one or more steps or operations. In some embodiments, the material of the second metal plug 62 shown in FIG. 8C can be ruthenium, for example. Even though the second metal plug 62 is illustrated and represented in the drawings as a single layer of one material, in some embodiments, this second metal plug 62 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the second metal plug 62 can be formed using physical vapor deposition (PVD), chemical vapor deposition (CVD), atomic layer deposition (ALD), or any combination thereof, for example.

Referring to FIG. 8D, the intermediate structure can be after a CMP processing operation, such as removing excess material formed on top of the third dielectric layer 53 during the forming or deposition of the second metal plug 62 and/or the second metal cap layer 82, for example. Notice that the resulting intermediate structure of FIG. 8D can be the same or equivalent to the resulting intermediate structure of FIG. 4E, but without the use of a SAM blocking layer to form the second metal cap layer 82, for example.

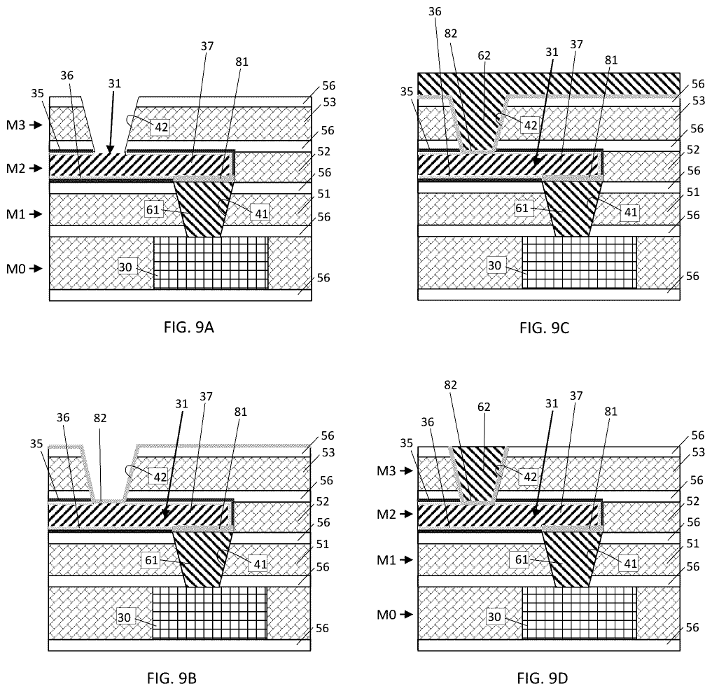

FIGS. 9A to 9D are cross-section views illustrating intermediate structures having metallization levels M0-M3 of a semiconductor device made using a method not using SAM according to an embodiment of the present disclosure. The intermediate structure shown in FIG. 9A can be the same as the intermediate structure shown in FIG. 4A and/or FIG. 8A, for example. And thus, for purposes of concise description, the embodiment of FIGS. 9A to 9D will be described as being built upon and continuing from the description of the intermediate structure of FIG. 4A, and the process steps and intermediate structures leading up to the intermediate structure of FIG. 4A will not be repeated here. Other embodiments can be made in accordance with the embodiment of FIGS. 9A to 9D with different underlying intermediate structures, such as not removing part of or all of the first SAM 71, not removing part of or all of the second SAM 72, or no use of SAM, for example.

Referring to FIG. 9B, a second metal cap layer 82 can be formed using a conformal deposition process, such as CVD and/or ALD, for example. Using CVD and/or ALD, for example, can form material of the second metal cap layer 82 on the opened first metallization layer 31 at a bottom of the second via 42 (and preferably completely covering the bottom of the second via 42 to completely cover the exposed first metallization layer 31 at the bottom of the second via 42), on a top surface of the third dielectric layer 53, and on sidewalls of the second via 42, partly not on upper portions of sidewalls of the second via 42, mostly not on sidewalls of the second via 42, or only very minimally on upper portions of sidewalls of second via 42 (e.g., thicker at lower portions of the sidewalls of the second via 42 than upper portions of the sidewalls of the second via 42). The machine used for the CVD and/or ALD, as well as the conditions and process parameters of the CVD and/or ALD can be adjusted, to control or vary the resulting structure and thickness of the second metal cap layer 82 formed. Hence, the intermediate structure including the formed second metal cap layer 82 illustrated in FIG. 9B can be somewhat simplified and idealized relative to an actual intermediate structure formed according to an embodiment of the present disclosure, as can be apparent to one of ordinary skill in the pertinent art.

Still referring to FIG. 9B, even though the second metal cap layer 82 is illustrated and represented in the drawings as a single layer of one material, in some embodiments, this second metal cap layer 82 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, such metal material(s) of the second metal cap layer 82 can include niobium, tungsten, tantalum, aluminum, alloys thereof, layers thereof, mixtures thereof, laminates thereof, or generally any combination thereof, for example.

Referring to FIG. 9C, the material for the second metal plug 62 can be formed for partially, mostly, completely, or overflowingly filling the second via 42. In some embodiments, the material of the second metal plug 62 shown in FIG. 9C can be ruthenium, for example. Even though the second metal plug 62 is illustrated and represented in the drawings as a single layer of one material, in some embodiments, this second metal plug 62 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the second metal plug 62 can be formed using physical vapor deposition (PVD), chemical vapor deposition (CVD), atomic layer deposition (ALD), or any combination thereof, for example.

Referring to FIG. 9D, the intermediate structure can be after a CMP processing operation, such as removing excess material formed on top of the third dielectric layer 53 during the forming or deposition of the second metal plug 62 and/or the second metal cap layer 82, for example.

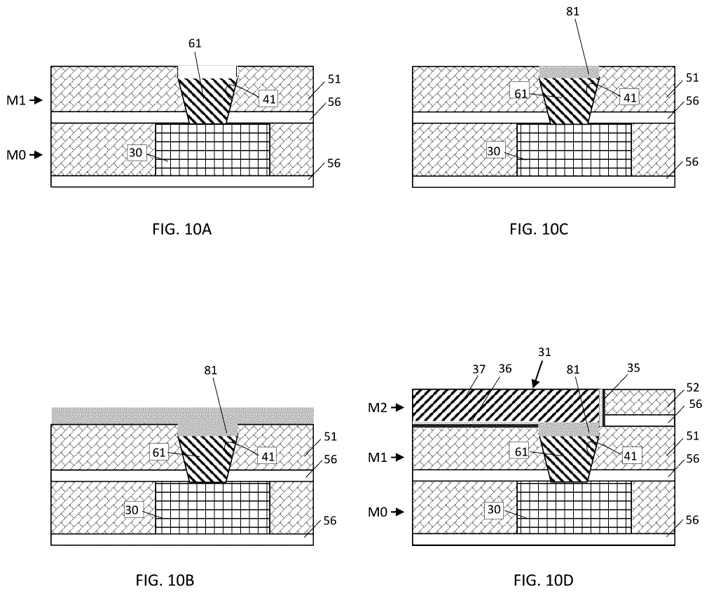

FIGS. 10A to 10D are cross-section views illustrating intermediate structures having metallization levels M0-M2 of a semiconductor device made using a method not using SAM according to an embodiment of the present disclosure. The intermediate structure shown in FIG. 10A can be the same as the intermediate structure shown in FIG. 2A, for example, except that the first metal plug 61 in the first via 41 can be formed differently.

Referring to FIG. 10A, the material for the first metal plug 61 can be a selective deposition of ruthenium such that the first via 41 is not completely filled. Alternatively, the material for the first metal plug 61 can be formed by alternating between deposition and etching of ruthenium, such as a deposition-etch-deposition process flow, such that the first via 41 is not completely filled. Even though the first metal plug 61 is illustrated and represented in the drawings as a single layer of one material, in some embodiments, this first metal plug 61 can be a single layer of one material, a single layer of an alloy or mix of multiple materials, multiple layers of one material, multiple layers of a same alloy or mix of multiple materials, or multiple layers of different materials or alloy(s) of materials, for example.

Referring to FIG. 10B, by not completely filling the first via 41 with the material for the first metal plug 61, an upper portion or upper volume of the first via 41 can remain open for forming a first metal cap layer 81 in that remaining open upper portion of the first via 41. The material for the first metal cap layer 81 can be formed for partially, mostly, completely, or overflowingly filling the first via 41. Still referring to FIG. 10B, even though the first metal cap layer 81 is illustrated and represented in the drawings as a single layer of one material, in some embodiments, this first metal cap layer 81 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, such metal material(s) of the first metal cap layer 81 can include niobium, tungsten, tantalum, aluminum, alloys thereof, layers thereof, mixtures thereof, laminates thereof, or generally any combination thereof, for example.

Referring to FIG. 10C, the intermediate structure can be after a CMP processing operation, such as removing excess material formed on top of the first dielectric layer 51 during the forming or deposition of the first metal plug 61 and/or the first metal cap layer 81, for example.

Referring to FIG. 10D, a second metal interconnect level M2 can be formed over the intermediate structure of FIG. 10C, which can include a first metallization layer 31 and a second dielectric layer 52, for example. Notice that the resulting intermediate structure of FIG. 10D can be the same or equivalent to the resulting intermediate structure of FIG. 2E, but without the use of SAM to form the first metal cap layer 81, for example.

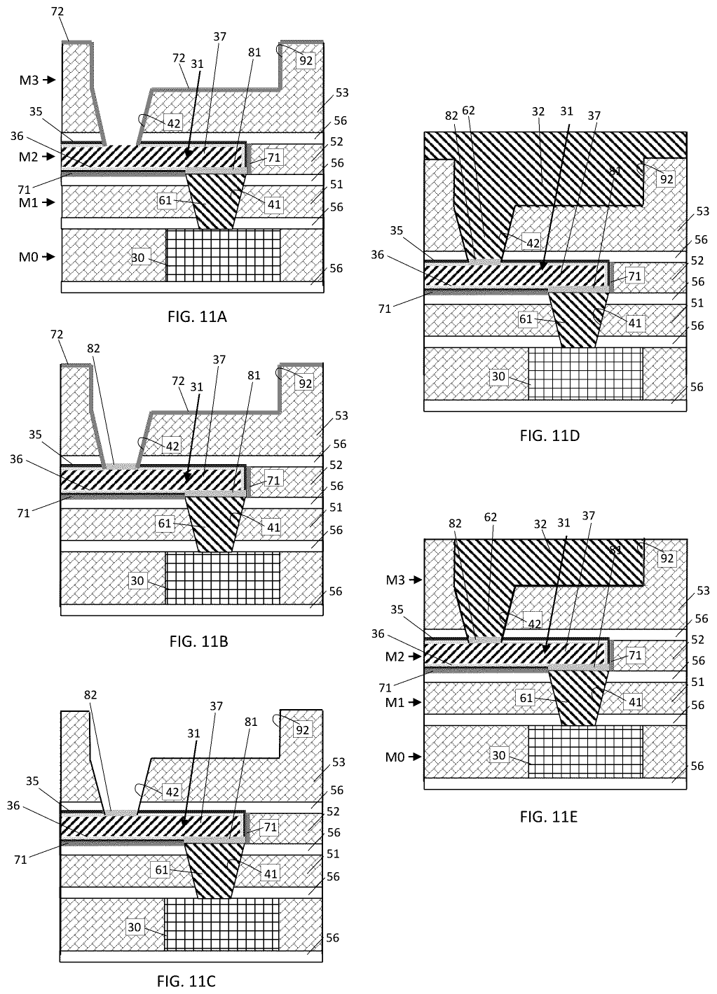

FIGS. 11A to 11E are cross-section views illustrating intermediate structures having metallization levels M0-M3 of a semiconductor device made using a method including a use of a SAM and removing part or all of the SAM, and including a dual damascene process flow, according to an embodiment of the present disclosure. Referring to FIG. 11A, a second via 42 and a second trench 92 are formed in a third dielectric layer 53, which were formed using a dual damascene process, and a second SAM 72 can be formed by selective deposition on the dielectric materials in the second via 42 and the second trench 92 of the dual damascene intermediate structure.

Referring to FIG. 11B, a second metal cap layer 82 can be formed by selective deposition in a bottom of the second via 42 directly on the underlying first metallization layer 31. Referring to FIG. 11C, part of, most of, or all of the second SAM 72 can be removed. Referring to FIG. 11D, a material or materials for a second metal plug 62 and a second metallization layer 32 can be formed in the second via 42 and second trench 92, respectively, for example using PVD, CVD, ALD, or any combination thereof. Referring to FIG. 11E, a planarization process (e.g., CMP) may be performed to remove excess materials from a top surface of the third dielectric layer 53 and to planarize and align a top surface of the third dielectric layer 53 with a top surface of the second metallization layer 32, for example. In some embodiments having an intermediate structure as illustrated in FIG. 11E, the second metal cap layer 82 can be niobium, the second metal plug 62 can be ruthenium formed directly on the dielectric material on the sidewalls of the second via 42, and the second metallization layer 32 can be ruthenium formed directly on the dielectric material in the second trench 92, for example.

An advantage of such intermediate structure of FIG. 11E while using a ruthenium-containing material is that such material of the second metal plug 62 and the second metallization layer 32 can be formed directly on the dielectric material(s) (e.g., including SiO2, SiN, SiCN, low-k, etch stop layer(s), or any combination thereof) without necessarily requiring a barrier layer therebetween, which can reduce device scale/size and allow for greater device density, for example. Another advantage of such process flow for forming the intermediate structures illustrated in FIGS. 11A to 11E is that the second metal plug 62 and the second metallization layer 32 can be formed in the second via 42 and the second trench 92 during a same process step or operation(s) in a same chamber, which can provide manufacturing efficiency in terms of time and costs.

As with the other embodiments described above, the materials of the second metal cap layer 82, the second metal plug 62, and the second metallization layer 32 can vary. Even though the second metal plug 62 and the second metallization layer 32 are illustrated and represented in FIGS. 11D and 11E as a single layer of one material, in some embodiments, this second metal plug 62 and/or the second metallization layer 32 can be a single layer of one material, a single layer of an alloy or mix of multiple materials, multiple layers of one material, multiple layers of a same alloy or mix of multiple materials, or multiple layers of different materials or alloy(s) of materials, for example.

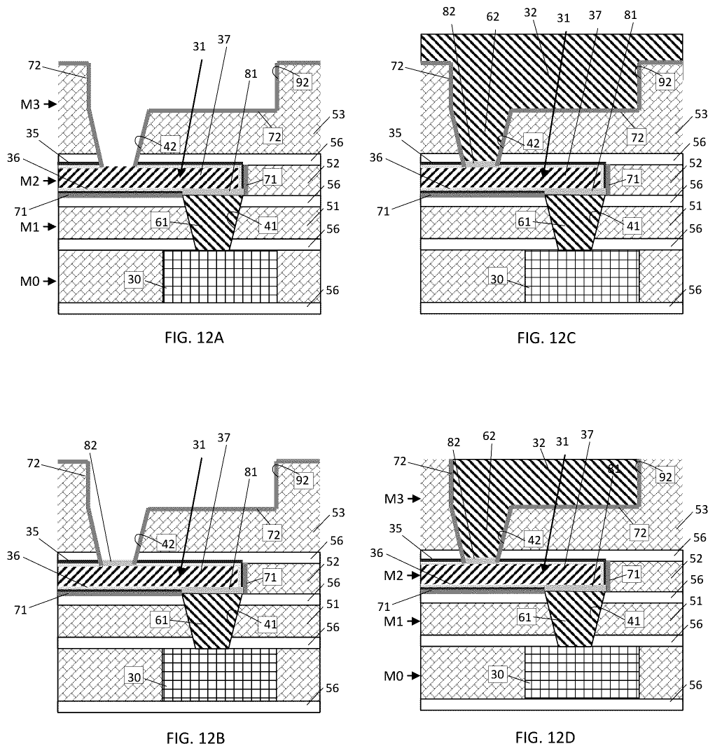

FIGS. 12A to 12D are cross-section views illustrating intermediate structures having metallization levels M0-M3 of a semiconductor device made using a method including a use of a SAM and not removing part or all of the SAM, and including a dual damascene process flow, according to an embodiment of the present disclosure. The process flow illustrated in FIGS. 12A to 12D can be the same as that shown in and described regarding FIGS. 11A to 11E, except that part of or all of the second SAM 72 is not removed after the formation of the second metal cap layer 82. Thus, referring to FIG. 12D, part of or all of the second SAM 72 can be remaining in the intermediate structure, and/or part of or all of a first SAM 71 can be remaining in the intermediate structure.

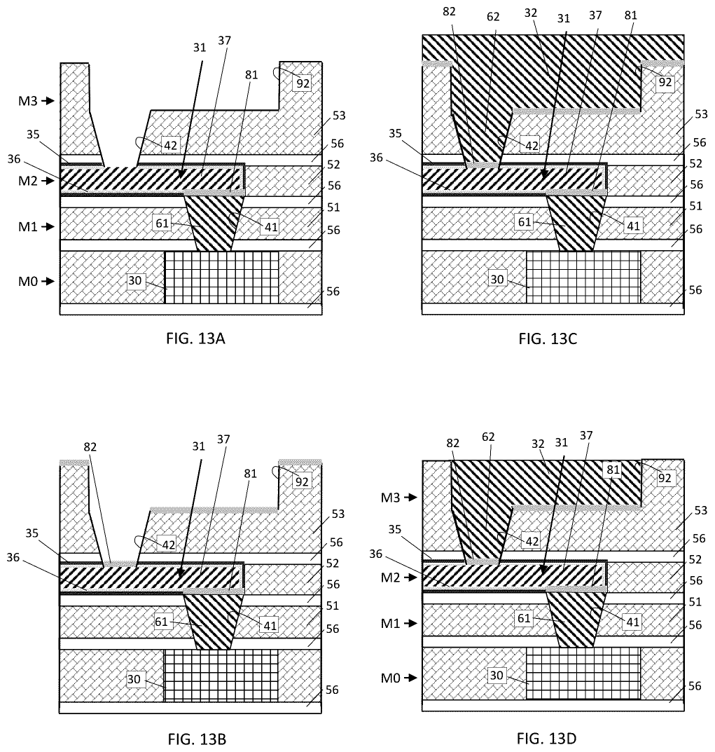

FIGS. 13A to 13D are cross-section views illustrating intermediate structures having metallization levels M0-M3 of a semiconductor device made using a method not using SAM, including a non-conformal formation of the second metal cap layer, and including a dual damascene process flow, according to an embodiment of the present disclosure. Referring to FIG. 13A, a second via 42 and a second trench 92 are formed in a third dielectric layer 53 at level M3, which were formed using a dual damascene process.

Referring to FIG. 13B, a second metal cap layer 82 can be formed using a non-conformal deposition process, such as PVD. Using PVD, for example, can form material of the second metal cap layer 82 on the opened first metallization layer 31 at a bottom of the second via 42 (and preferably completely covering the bottom of the second via 42 to completely cover the exposed first metallization layer 31 at the bottom of the second via 42), on a top surface of the second trench 92, on a top surface of the third dielectric layer 52, but not on the sidewalls of the second trench 92, partly not on upper portions of the sidewalls of the second trench 92, mostly not on the sidewalls of the second trench 92, or only very minimally on upper portions of the sidewalls of second trench 92 (e.g., thicker at lower portions of the sidewalls of the second trench 92 than upper portions of the sidewalls of the second trench 92), and not on the sidewalls of the second via 42, partly not on upper portions of the sidewalls of the second via 42, mostly not on the sidewalls of the second via 42, or only very minimally on upper portions of the sidewalls of second via 42 (e.g., thicker at lower portions of the sidewalls of the second via 42 than upper portions of the sidewalls of the second via 42).

Referring to FIG. 13C, a material or materials for a second metal plug 62 and a second metallization layer 32 can be formed in the second via 42 and second trench 92, respectively, for example using PVD, CVD, ALD, or any combination thereof. Referring to FIG. 13D, a planarization process (e.g., CMP) may be performed to remove excess materials from a top surface of the third dielectric layer 53 and to planarize and align a top surface of the third dielectric layer 53 with a top surface of the second metallization layer 32. In some embodiments having an intermediate structure as illustrated in FIG. 13D, the second metal cap layer 82 can be niobium, the second metal plug 62 can be ruthenium formed directly on the dielectric material on the sidewalls of the second via 42, and the second metallization layer 32 can be ruthenium formed directly on the dielectric material in the second trench 92, for example.

An advantage of such intermediate structure of FIG. 13D while using a ruthenium-containing material is that such material of the second metal plug 62 and the second metallization layer 32 can be formed directly on the dielectric material(s) (e.g., including SiO2, SiN, SiCN, low-k, etch stop layer(s), or any combination thereof) without necessarily requiring a barrier layer therebetween, which can reduce device scale/size and allow for greater device density, for example. Another advantage of such process flow for forming the intermediate structures illustrated in FIGS. 13A to 13D is that the second metal plug 62 and the second metallization layer 32 can be formed in the second via 42 and the second trench 92 during a same process step or operation(s) in a same chamber, which can provide manufacturing efficiency in terms of time and costs. In some embodiments and another advantage of such process flow for forming the intermediate structures illustrated in FIGS. 13A to 13D is that the second metal cap layer 82, second metal plug 62, and the second metallization layer 32 can be formed in the second via 42 and the second trench 92 during in a same chamber without removing the substrate from the chamber for those steps (e.g., avoiding exposure of the materials to non-vacuum or atmosphere), which can provide manufacturing efficiency in terms of time and costs.

As with the other embodiments described above, the materials of the second metal cap layer 82, the second metal plug 62, and the second metallization layer 32 can vary. Even though the second metal plug 62 and the second metallization layer 32 are illustrated and represented in FIGS. 13C and 13D as a single layer of one material, in some embodiments, this second metal plug and/or the second metallization layer can be a single layer of one material, a single layer of an alloy or mix of multiple materials, multiple layers of one material, multiple layers of a same alloy or mix of multiple materials, or multiple layers of different materials or alloy(s) of materials, for example.

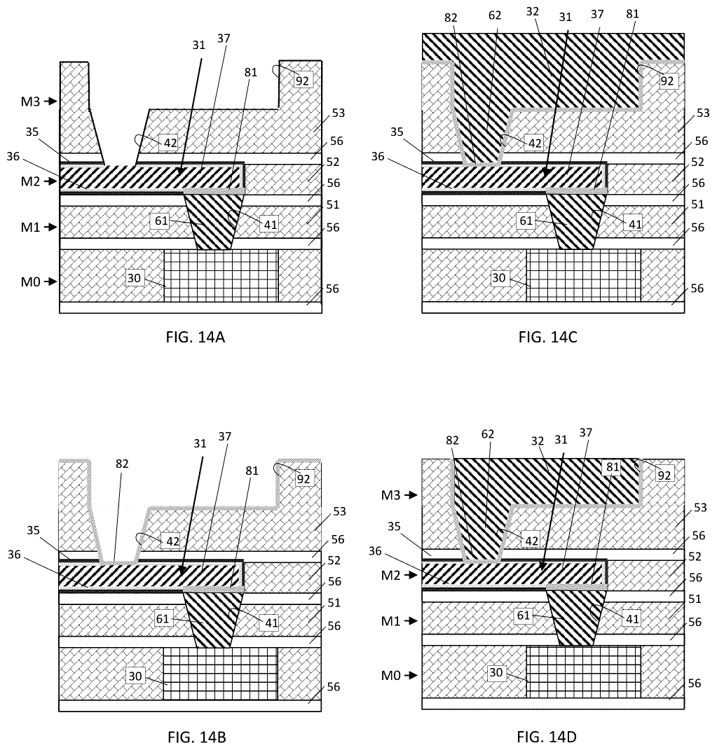

FIGS. 14A to 14D are cross-section views illustrating intermediate structures having metallization levels M0-M3 of a semiconductor device made using a method not using SAM, including a conformal formation of the second metal cap layer, and including a dual damascene process flow, according to an embodiment of the present disclosure. Referring to FIG. 14A, a second via 42 and a second trench 92 are formed in a third dielectric layer 53, which were formed using a dual damascene process.

Referring to FIG. 14B, a second metal cap layer 82 can be formed using a conformal deposition process, such as CVD and/or ALD, for example. Using CVD and/or ALD, for example, can form material of the second metal cap layer 82 on the opened first metallization layer 31 at a bottom of the second via 42 (and preferably completely covering the bottom of the second via 42 to completely cover the exposed first metallization layer 31 at the bottom of the second via 42), in the second trench 92, on a top surface of the third dielectric layer 52, on the sidewalls of the second trench 92, partly not on upper portions of the sidewalls of the second trench 92, mostly not on the sidewalls of the second trench 92, or only very minimally on upper portions of the sidewalls of second trench 92 (e.g., thicker at lower portions of the sidewalls of the second trench 92 than upper portions of the sidewalls of the second trench 92), and on the sidewalls of the second via 42, partly not on upper portions of the sidewalls of the second via 42, mostly not on the sidewalls of the second via 42, or only very minimally on upper portions of the sidewalls of second via 42 (e.g., thicker at lower portions of the sidewalls of the second via 42 than upper portions of the sidewalls of the second via 42).

Referring to FIG. 14C, a material or materials for a second metal plug 62 and a second metallization layer 32 can be formed in the second via 42 and second trench 92, respectively, for example using PVD, CVD, ALD, or any combination thereof. Referring to FIG. 14D, a planarization process (e.g., CMP) may be performed to remove excess materials from a top surface of the third dielectric layer 53 and to planarize and align a top surface of the third dielectric layer 53 with a top surface of the second metallization layer 32. In some embodiments having an intermediate structure as illustrated in FIG. 14D, the second metal cap layer 82 can be niobium, the second metal plug 62 can be ruthenium formed directly on the dielectric material on the sidewalls of the second via 42, and the second metallization layer 32 can be ruthenium formed directly on the dielectric material in the second trench 92, for example.

### Experimental Results

Different metal cap layer materials were evaluated as barriers to metal intermixing. For example, some test structures contained film laminates of TaN/Co/Cu/Ru and TaN/Co/Cu/Nb/Ru. In some embodiments, a cap layer 81, 82, 83, 84 can be Nb, Al, Mn, Mo, alloys thereof, or any combination thereof, for example. In some example experiments, Nb cap layers had thicknesses of 1 nm, 3.5 nm, and 14 nm. In some embodiments, a cap layer 81, 82, 83, 84 can have a thickness in a range of 1 angstrom to 150 angstroms, for example. In some example experiments, the elemental composition of exposed surfaces of test structures was analyzed by x-ray photoelectron spectroscopy (XPS) before and after annealing at 400° C. for 1 hour. In some embodiments, an annealing condition can be 300-400 degrees Celsius for more than 30 minutes, for example. The elemental analysis showed intermixing of Co, Cu and Ru after annealing for the TaN/Co/Cu/Ru test structure but test samples containing the Nb cap layers prevented intermixing of Co and Cu with Ru. This shows that a Nb cap layer with a thickness of 1 nm, or greater, was an effective metal cap layer for preventing intermixing of Co and Cu with Ru.

Some other test structures contained film laminates of Co/Ru and Co/Nb/Ru. The Nb cap layers had thicknesses of 1 nm, 2 nm, and 4 nm. The analysis showed intermixing of Co and Ru after annealing for the Co/Ru test structure at 400° C. for 1 hour but the 2 nm and 4 nm Nb cap layers prevented intermixing of Co with Ru. This shows that a Nb cap layer with a thickness of about 2 nm, or greater, was an effective metal cap layer for preventing intermixing of Co with Ru.

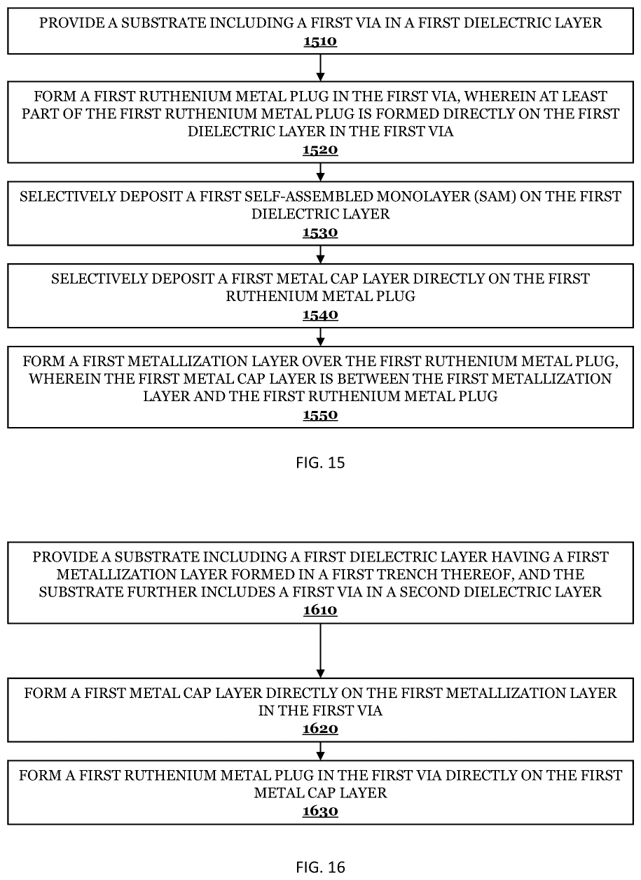

FIG. 15 illustrates a flow chart implementing the metal cap layer in accordance with an embodiment of the present disclosure.

In an embodiment, a method for forming a semiconductor device includes providing a substrate including a first via in a first dielectric layer (box 1510). The method includes forming a first ruthenium metal plug in the first via, where at least part of the first ruthenium metal plug is formed directly on the first dielectric layer in the first via (box 1520). The method includes selectively depositing a first self-assembled monolayer (SAM) on the first dielectric layer (box 1530). The method includes selectively depositing a first metal cap layer directly on the first ruthenium metal plug (box 1540). The method includes forming a first metallization layer over the first ruthenium metal plug, where the first metal cap layer is between the first metallization layer and the first ruthenium metal plug (box 1550).

FIG. 16 illustrates a flow chart implementing the metal cap layer in accordance with an embodiment of the present disclosure.

In an embodiment, a method for forming a semiconductor device includes providing a substrate including a first dielectric layer having a first metallization layer formed in a first trench thereof, and the substrate further includes a first via in a second dielectric layer, where the second dielectric layer is over at least part of the first dielectric layer and over at least part of the first metallization layer, and where the first via opens to the first metallization layer (box 1610). The method includes forming a first metal cap layer directly on the first metallization layer in the first via (box 1620). The method includes forming a first ruthenium metal plug in the first via directly on the first metal cap layer (box 1630).

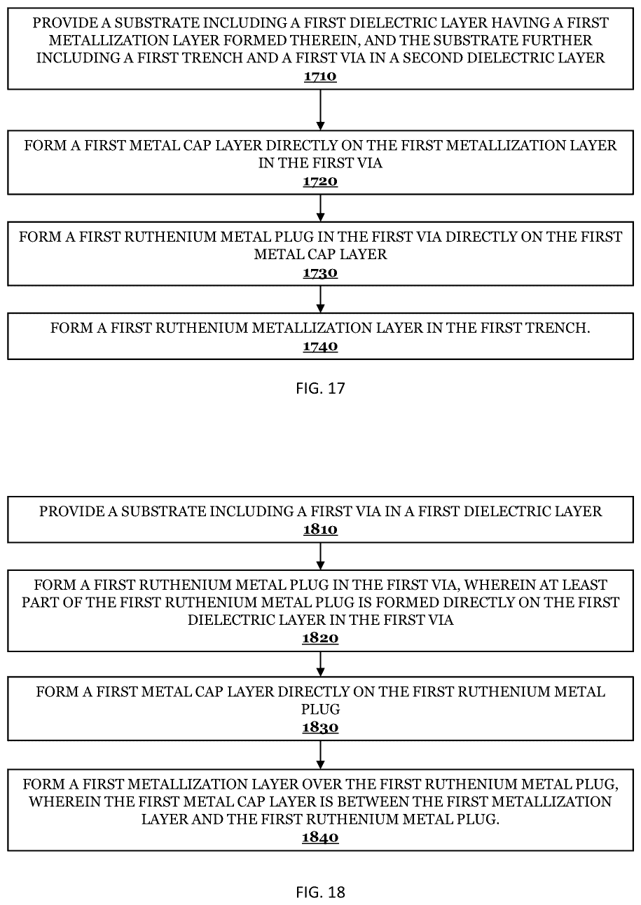

FIG. 17 illustrates a flow chart implementing the metal cap layer in accordance with an embodiment of the present disclosure.

In an embodiment, a method for forming a semiconductor device includes providing a substrate including a first dielectric layer having a first metallization layer formed therein, and the substrate further including a first trench and a first via in a second dielectric layer, where the second dielectric layer is over at least part of the first dielectric layer and over at least part of the first metallization layer, and where the first via opens to the first metallization layer connecting the first metallization layer to the first trench (box 1710). The method includes forming a first metal cap layer directly on the first metallization layer in the first via (box 1720). The method includes forming a first ruthenium metal plug in the first via directly on the first metal cap layer (box 1730). The method includes forming a first ruthenium metallization layer in the first trench (box 1740).

FIG. 18 illustrates a flow chart implementing the metal cap layer in accordance with an embodiment of the present disclosure.

In an embodiment, a method for forming a semiconductor device includes providing a substrate including a first via in a first dielectric layer (box 1810). The method includes forming a first ruthenium metal plug in the first via, where at least part of the first ruthenium metal plug is formed directly on the first dielectric layer in the first via (box 1820). The method includes forming a first metal cap layer directly on the first ruthenium metal plug (box 1830). The method includes forming a first metallization layer over the first ruthenium metal plug, where the first metal cap layer is between the first metallization layer and the first ruthenium metal plug (box 1840).

The embodiments described in FIGS. 15-18 may be implemented as further described using FIGS. 1-14D.

More example embodiments of the present disclosure are summarized here. Other embodiments can also be understood from the entirety of the specification as well as the claims filed herein.

Example 1. A method for forming a semiconductor device, the method comprising: providing a substrate including a first via in a first dielectric layer; forming a first ruthenium metal plug in the first via, where at least part of the first ruthenium metal plug is formed directly on the first dielectric layer in the first via; selectively depositing a first self-assembled monolayer (SAM) on the first dielectric layer; selectively depositing a first metal cap layer directly on the first ruthenium metal plug; and forming a first metallization layer over the first ruthenium metal plug, where the first metal cap layer is between the first metallization layer and the first ruthenium metal plug.

Example 2. The method of example 1, further comprising removing the first SAM before the forming of the first metallization layer.

Example 3. The method of one of examples 1 to 2, where the first metallization layer includes one of or any combination of copper metal, cobalt-doped copper metal, and alloys thereof; where the first metal cap layer includes one of or any combination of a niobium metal layer, a tungsten metal layer, a tantalum metal layer, an aluminum metal layer, a manganese layer, a molybdenum metal layer, and alloys thereof; and where the first metal cap layer has a same width as a top of the first ruthenium metal plug.

Example 4. The method of one of examples 1 to 3, further comprising: forming a second dielectric layer over the first metallization layer; forming a second via in the second dielectric layer opening to the first metallization layer; selectively depositing a second SAM on the second dielectric layer; selectively depositing a second metal cap layer directly on the first metallization layer; and forming a second ruthenium metal plug in the first via directly on the second metal cap layer.

Example 5. The method of one of examples 1 to 4, further comprising: removing the first SAM before the forming of the first metallization layer; and removing the second SAM before the forming of the second ruthenium metal plug, where at least part of the second ruthenium metal plug is formed directly on the second dielectric layer in the second via.

Example 6. The method of one of examples 1 to 5, where the first metallization layer includes one of or both of copper metal and cobalt-doped copper metal; and where each of the first metal cap layer and the second metal cap layer includes one of or any combination of a niobium metal layer, a tungsten metal layer, a tantalum metal layer, an aluminum metal layer, a manganese layer, a molybdenum metal layer, and alloys thereof.

Example 7. A method for forming a semiconductor device, the method comprising: providing a substrate including a first dielectric layer having a first metallization layer formed in a first trench thereof, and the substrate further includes a first via in a second dielectric layer, where the second dielectric layer is over at least part of the first dielectric layer and over at least part of the first metallization layer, and where the first via opens to the first metallization layer; forming a first metal cap layer directly on the first metallization layer in the first via; and forming a first ruthenium metal plug in the first via directly on the first metal cap layer.

Example 8. The method of example 7, further comprising: selectively depositing a first self-assembled monolayer (SAM) on the second dielectric layer, before the forming of the first metal cap layer, where the forming of the first metal cap layer comprises selectively depositing the first metal cap layer directly on the first metallization layer.

Example 9. The method of one of examples 7 to 8, further comprising removing the first SAM before the forming of the first ruthenium metal plug, where at least part of the first ruthenium metal plug is formed directly on the second dielectric layer in the first via.

Example 10. The method of one of examples 7 to 9, where the first metallization layer includes one of or both of copper metal and cobalt-doped copper metal, and where the first metal cap layer includes one of or any combination of a niobium metal layer, a tungsten metal layer, a tantalum metal layer, an aluminum metal layer, a manganese layer, a molybdenum metal layer, and alloys thereof.

Example 11. The method of one of examples 7 to 10, where the forming of the first metal cap layer uses physical vapor deposition, where at least part of the first ruthenium metal plug is formed directly on the second dielectric layer in the first via.

Example 12. The method of one of examples 7 to 11, where the first metallization layer includes one of or both of copper metal and cobalt-doped copper metal, and where the first metal cap layer includes one of or any combination of a niobium metal layer, a tungsten metal layer, a tantalum metal layer, an aluminum metal layer, a manganese layer, a molybdenum metal layer, and alloys thereof.

Example 13. The method of one of examples 7 to 12, where the forming of the first metal cap layer uses chemical vapor deposition or atomic layer deposition, where at least part of the first metal cap layer is formed on at least part of a sidewall of the first via.

Example 14. The method of one of examples 7 to 13, where the first metallization layer includes one of or both of copper metal and cobalt-doped copper metal, and where the first metal cap layer includes one of or any combination of a niobium metal layer, a tungsten metal layer, a tantalum metal layer, an aluminum metal layer, a manganese layer, a molybdenum metal layer, and alloys thereof.

Example 15. The method of one of examples 7 to 14, further comprising: forming a second trench in a third dielectric layer, where the third dielectric layer is formed over at least part of the second dielectric layer, and where at least part of the second trench opens to the first ruthenium metal plug; selectively depositing a first self-assembled monolayer (SAM) on the third dielectric layer; and selectively depositing a second metal cap layer directly on the first ruthenium metal plug.

Example 16. The method of one of examples 7 to 15, where the first metallization layer includes one of or both of copper metal and cobalt-doped copper metal; where each of the first metal cap layer and the second metal cap layer includes one of or any combination of a niobium metal layer, a tungsten metal layer, a tantalum metal layer, an aluminum metal layer, a manganese layer, a molybdenum metal layer, and alloys thereof; and where the second metal cap layer has a same width as a top of the first ruthenium metal plug.

Example 17. A method for forming a semiconductor device, the method comprising: providing a substrate including a first dielectric layer having a first metallization layer formed therein, and the substrate further including a first trench and a first via in a second dielectric layer, where the second dielectric layer is over at least part of the first dielectric layer and over at least part of the first metallization layer, and where the first via opens to the first metallization layer connecting the first metallization layer to the first trench; forming a first metal cap layer directly on the first metallization layer in the first via; forming a first ruthenium metal plug in the first via directly on the first metal cap layer; and forming a first ruthenium metallization layer in the first trench.

Example 18. The method of example 17, further comprising: selectively depositing a first self-assembled monolayer (SAM) on the second dielectric layer, before the forming of the first metal cap layer, where the forming of the first metal cap layer comprises selectively depositing the first metal cap layer directly on the first metallization layer; and removing the first SAM before the forming of the first ruthenium metal plug, where at least part of the first ruthenium metal plug is formed directly on the second dielectric layer in the first via, where the first metallization layer includes one of or both of copper metal and cobalt-doped copper metal, and where the first metal cap layer includes one of or any combination of a niobium metal layer, a tungsten metal layer, a tantalum metal layer, an aluminum metal layer, a manganese layer, a molybdenum metal layer, and alloys thereof.

Example 19. The method of one of examples 17 to 18, where the forming of the first metal cap layer uses physical vapor deposition, where at least part of the first ruthenium metal plug is formed directly on the second dielectric layer in the first via, where the first metallization layer includes one of or both of copper metal and cobalt-doped copper metal, and where the first metal cap layer includes one of or any combination of a niobium metal layer, a tungsten metal layer, a tantalum metal layer, an aluminum metal layer, a manganese layer, a molybdenum metal layer, and alloys thereof.

Example 20. A method for forming a semiconductor device, the method comprising: providing a substrate including a first via in a first dielectric layer; forming a first ruthenium metal plug in the first via, where at least part of the first ruthenium metal plug is formed directly on the first dielectric layer in the first via; forming a first metal cap layer directly on the first ruthenium metal plug; and forming a first metallization layer over the first ruthenium metal plug, where the first metal cap layer is between the first metallization layer and the first ruthenium metal plug.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

1. A method for forming a semiconductor device, the method comprising:
providing a substrate including a first via in a first dielectric layer;
forming a first ruthenium metal plug in the first via, wherein at least part of the first ruthenium metal plug is formed directly on the first dielectric layer in the first via;
selectively depositing a first self-assembled monolayer (SAM) on the first dielectric layer;
selectively depositing a first metal cap layer directly on the first ruthenium metal plug; and
forming a first metallization layer over the first ruthenium metal plug, wherein the first metal cap layer is between the first metallization layer and the first ruthenium metal plug.

2. The method of claim 1, further comprising removing the first SAM before the forming of the first metallization layer.

3. The method of claim 1, wherein the first metallization layer includes one of or any combination of copper metal, cobalt-doped copper metal, and alloys thereof; wherein the first metal cap layer includes one of or any combination of a niobium metal layer, a tungsten metal layer, a tantalum metal layer, an aluminum metal layer, a manganese layer, a molybdenum metal layer, and alloys thereof; and wherein the first metal cap layer has a same width as a top of the first ruthenium metal plug.

4. The method of claim 1, further comprising:
forming a second dielectric layer over the first metallization layer;
forming a second via in the second dielectric layer opening to the first metallization layer;
selectively depositing a second SAM on the second dielectric layer;
selectively depositing a second metal cap layer directly on the first metallization layer; and
forming a second ruthenium metal plug in the first second via directly on the second metal cap layer.

5. The method of claim 4, further comprising:
removing the first SAM before the forming of the first metallization layer; and
removing the second SAM before the forming of the second ruthenium metal plug, wherein at least part of the second ruthenium metal plug is formed directly on the second dielectric layer in the second via.

6. The method of claim 4, wherein the first metallization layer includes one of or both of copper metal and cobalt-doped copper metal; and wherein each of the first metal cap layer and the second metal cap layer includes one of or any combination of a niobium metal layer, a tungsten metal layer, a tantalum metal layer, an aluminum metal layer, a manganese layer, a molybdenum metal layer, and alloys thereof.

7. A method for forming a semiconductor device, the method comprising:
providing a substrate including a first dielectric layer having a first metallization layer formed in a first trench thereof, and the substrate further includes a first via in a second dielectric layer, wherein the second dielectric layer is over at least part of the first dielectric layer and over at least part of the first metallization layer, and wherein the first via opens to the first metallization layer;
forming a first metal cap layer directly on the first metallization layer in the first via; and
forming a first ruthenium metal plug in the first via directly on the first metal cap layer.

8. The method of claim 7, further comprising selectively depositing a first self-assembled monolayer (SAM) on the second dielectric layer, before the forming of the first metal cap layer, wherein the forming of the first metal cap layer comprises selectively depositing the first metal cap layer directly on the first metallization layer.

9. The method of claim 8, further comprising removing the first SAM before the forming of the first ruthenium metal plug, wherein at least part of the first ruthenium metal plug is formed directly on the second dielectric layer in the first via.

10. The method of claim 9, wherein the first metallization layer includes one of or both of copper metal and cobalt-doped copper metal, and wherein the first metal cap layer includes one of or any combination of a niobium metal layer, a tungsten metal layer, a tantalum metal layer, an aluminum metal layer, a manganese layer, a molybdenum metal layer, and alloys thereof.

11. The method of claim 7, wherein the forming of the first metal cap layer uses physical vapor deposition, wherein at least part of the first ruthenium metal plug is formed directly on the second dielectric layer in the first via.

12. The method of claim 11, wherein the first metallization layer includes one of or both of copper metal and cobalt-doped copper metal, and wherein the first metal cap layer includes one of or any combination of a niobium metal layer, a tungsten metal layer, a tantalum metal layer, an aluminum metal layer, a manganese layer, a molybdenum metal layer, and alloys thereof.

13. The method of claim 7, wherein the forming of the first metal cap layer uses chemical vapor deposition or atomic layer deposition, wherein at least part of the first metal cap layer is formed on at least part of a sidewall of the first via.

14. The method of claim 11, wherein the first metallization layer includes one of or both of copper metal and cobalt-doped copper metal, and wherein the first metal cap layer includes one of or any combination of a niobium metal layer, a tungsten metal layer, a tantalum metal layer, an aluminum metal layer, a manganese layer, a molybdenum metal layer, and alloys thereof.

15. The method of claim 7, further comprising:
forming a second trench in a third dielectric layer, wherein the third dielectric layer is formed over at least part of the second dielectric layer, and wherein at least part of the second trench opens to the first ruthenium metal plug;
selectively depositing a first self-assembled monolayer (SAM) on the third dielectric layer; and
selectively depositing a second metal cap layer directly on the first ruthenium metal plug.

16. The method of claim 15, wherein the first metallization layer includes one of or both of copper metal and cobalt-doped copper metal; wherein each of the first metal cap layer and the second metal cap layer includes one of or any combination of a niobium metal layer, a tungsten metal layer, a tantalum metal layer, an aluminum metal layer, a manganese layer, a molybdenum metal layer, and alloys thereof; and wherein the second metal cap layer has a same width as a top of the first ruthenium metal plug.

17. A method for forming a semiconductor device, the method comprising:
providing a substrate including a first via in a first dielectric layer;
forming a first ruthenium metal plug in the first via, wherein at least part of the first ruthenium metal plug is formed directly on the first dielectric layer in the first via;
forming a first metal cap layer directly on the first ruthenium metal plug; and
forming a first metallization layer over the first ruthenium metal plug, wherein the first metal cap layer is between the first metallization layer and the first ruthenium metal plug.

18. The method of claim 17, further comprising selectively depositing a first self-assembled monolayer (SAM) on the first dielectric layer, before the forming of the first metal cap layer, wherein the forming of the first metal cap layer comprises selectively depositing the first metal cap layer directly on the first metallization layer.

19. The method of claim 18, further comprising removing the first SAM before the forming of the first metallization layer.

20. The method of claim 17, wherein the first metallization layer includes one of or both of copper metal and cobalt-doped copper metal, and wherein the first metal cap layer includes one of or any combination of a niobium metal layer, a tungsten metal layer, a tantalum metal layer, an aluminum metal layer, a manganese layer, a molybdenum metal layer, and alloys thereof.
